(19) United States
(12) Patent Application Publication
(10) Pub. No.: US 2010/0319854 A1
(43) Pub. Date: Dec. 23, 2010

(54) PLASMA PROCESSING APPARATUS

(76) Inventors: Kenetsu YOKOGAWA, Tsurugashima (JP); Kenji Maeda, Koganei (JP); Tomoyuki Tamura, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/546,783

(22) Filed: Aug. 25, 2009

(30) Foreign Application Priority Data
Jun. 23, 2009 (JP) 2009-148189

(51) Int. Cl. H01L 21/3065

(52) U.S. Cl. 156/345.34

(57) ABSTRACT

In a plasma processing apparatus conducting surface processing on a sample to be processed with plasma, an upper electrode includes a shower plate having first gas holes bored through it, a conductor plate disposed at back of the shower plate and having second gas holes bored through it, an insulation plate disposed in a center part of the conductor plate and having third gas holes bored through it, and an antenna basic member unit disposed at back of the conductor plate and having a temperature control function unit and a gass distribution unit. First and second minute gaps are formed in a radial direction at an interface between the shower plate and the insulation plate, and at an interface between the insulation plate and the conductor plate, respectively. Centers of the first gas holes are shifted from centers of the third gas holes in a circumference or radial direction.

### BACKGROUND OF THE INVENTION

The present invention relates to a semiconductor manufacturing apparatus which conducts surface processing (for example, etching) on a sample to be processed (for example, a semiconductor device). In particular, the present invention relates to a plasma processing apparatus which etches a semiconductor material such as silicon or a silicon oxide film by using plasma in pursuance of a shape of a mask pattern formed of a resist material or the like.

Dry etching is a minute semiconductor processing method for obtaining a desired shape by introducing gasses into a vacuum vessel having a vacuum evacuation unit, converting the gasses to plasma by using an electromagnetic wave, exposing a sample to be processed to the plasma, and etching parts other than a masked part of the surface of the sample to be processed. The processing uniformity in the surface of the sample to be processed is influenced by plasma distribution, temperature distribution in the surface of the sample to be processed, and composition and flow distribution of the supply gas. Especially in a parallel plate plasma processing apparatus, gasses is supplied from a shower plate disposed opposite to the sample to be processed and the distance between the sample to be processed and the shower plate is comparatively short, and consequently supply distribution of gas supplied from the shower plate exerts influence upon the processing speed and processing shape. However, a high frequency voltage for plasma generation is applied to the shower plate, and there is a problem that local discharge is caused in a gas supply unit provided on the shower plate by the high frequency voltage. If discharge occurs in minute holes serving as the gas supply unit, etching characteristics at the discharge place is locally disturbed because the sample to be processed is opposed to the minute holes with a short distance between, resulting in a problem of occurrence of dust particles.

The mechanism of occurrence of abnormal discharge (or anomalous discharge) in gas holes (gas holes located near the shower plate and an interface of a conductor plate disposed at the back of the shower plate) of the shower plate will now be described briefly. As for the material of the shower plate, silicon is used. The shower plate is disposed so as to be at its back in contact with a conductor plate formed of metal such as aluminum and adjusted in temperature. Furthermore, a large number of minute holes are formed in the shower plate as the gas supply unit. Since silicon forming the shower plate is semiconductor, its electric resistivity is comparatively high (between 1 and several tens Ω·cm both inclusive) and the electromagnetic wave used to generate plasma sufficiently penetrates in the thickness direction. As a result, an electromagnetic wave electric field exists between the shower plate and the above-described metallic conductor plate. On the other hand, since the metallic conductor plate is a good conductor, the electromagnetic wave which has penetrated in the thickness direction of the shower plate abruptly attenuates at the conductor surface. As a result, an alternating current potential difference occurs at an interface between the shower plate and the metallic conductor plate. The potential difference acts on space of gas holes formed in the shower plate and the conductor plate, and causes abnormal discharge. Furthermore, accelerated ions which come from (or pass from) the plasma via the gas holes of the shower plate assist generation of the abnormal discharge.

As a related art for suppressing the abnormal discharge caused in the minute holes of the shower plate, it is described in, for example, JP-A-2003-68718 to insert a member formed of an insulation material such as quartz in a center part between the shower plate and the conductor plate disposed at the back of the shower plate. This aims at moderating the high frequency electric field strength in the center part of the shower plate where abnormal discharge is apt to occur with the insulation material disposed at its back and thereby suppressing occurrence of abnormal discharge. If the frequency of the high frequency electric field for plasma generation supplied to the shower plate is in a high frequency band of at least several tens MHz, then the electric field strength distribution on the surface of the shower plate tends to become strong near the center, and abnormal discharge becomes apt to occur in gas holes near the center of the shower plate under its influence. Since the insulation material used in the related art is disposed only near the center, the insulation material moderates the electric field strength near the center where abnormal discharge is apt to occur and suppresses the abnormal discharge. By setting the arrangement range of the insulation material to the vicinity of the center, it becomes possible to bring a great part of the shower plate into contact with the conductor plate installed at the back of the shower plate and adjusted in temperature and it becomes possible to cool or adjust the temperature of the shower plate itself.

In a structure described in JP-A-2007-5491, a shower plate formed of a conductor such as silicon is divided in the thickness direction, and positions of gas holes penetrating each of the divisions obtained by dividing the shower plate are changed. This aims at suppressing the penetration of ions which becomes a cause of ignition of abnormal discharge from plasma and thereby enhancing the suppression effect of the abnormal discharge.

However, the related arts have respective problems described hereafter.

In the related art described in JP-A-2003-68718, only the electric field strength of the high frequency electric field is relatively weakened. According to the discharge condition, therefore, the effect is insufficient in some cases and abnormal discharge occurs in the gas holes in some cases. Since gas is also released from the vicinity of the center where the insulation material is disposed, gas holes made coincident with those of the shower plate are formed in the insulation material as well. If power of the electromagnetic wave for plasma generation supplied to the shower plate is increased or the flow rate of gas released from gas holes is increased, the risk of abnormal discharge in the gas holes tends to become high. Abnormal discharge in the gas holes occurs due to expansion or the like of the diameter of gas holes which is caused by consumption of the shower plate, and abnormal discharge occurs as a result of a change with the passage of time in some cases. Even if the shower plate has a sufficient thickness in this case, abnormal discharge is caused by expansion of the gas holes and the life of the shower plate which is an article of consumption is restricted by the occurrence of the abnormal discharge, resulting in an increased cost of articles of consumption.

The related art described in JP-A-2007-5491 aims at only suppressing arrival of ions from plasma which pass through the gas holes of the shower plate which is a conductor and arrives at the back of the shower plate (a region which causes the abnormal discharge). Therefore, the potential difference (a direct cause of the abnormal discharge) between the shower plate and the conductor plate installed at the back of the shower plate is not influenced at all. Therefore, there is a limit in the suppression effect of abnormal discharge. Furthermore, since the shower plate is divided in the thickness direction, thermal conductivity falls remarkably in each divisional part. Therefore, temperature control (cooling) of the shower plate in contact with plasma becomes difficult, resulting in evils such as stability lowering of the process and exhaustion increase of the shower plate.

### SUMMARY OF THE INVENTION

The present invention has been made in view of the problems, and an object thereof is to suppress the abnormal discharge occurring in the shower plate gas holes and substantially improve the process performance owing to occurrence prevention of plasma instability and dust particles caused by the abnormal discharge, a prolonged life of the shower plate, and expansion of the conditional range in which plasma can be generated.

In order to achieve the object, the present invention adopts the following means.

A plasma processing apparatus which conducts surface processing on a sample to be processed by using plasma includes a vacuum vessel within which the plasma is generated, a lower electrode which is provided in the vacuum vessel and on which the sample to be processed is placed, an upper electrode provided so as to be opposed to the lower electrode, a gass supply unit connected to the upper electrode, a high frequency power supply for plasma generation connected to the upper electrode, and a solenoid coil for magnetic field generation. The upper electrode includes a shower plate through which first gas holes are formed, a conductor plate which is disposed at back of the shower plate and through which second gas holes are formed, an insulation plate which is disposed in a center part of the conductor plate and through which third gas holes are formed, and an antenna basic member unit which is disposed at back of the conductor plate and which has a temperature control function unit and a gass distribution unit. A first minute gap is formed in a radial direction at an interface between the shower plate and the insulation plate, and a second minute gap is formed in a radial direction at an interface between the insulation plate and the conductor plate. And centers of the first gas holes are shifted from centers of the third gas holes in a circumference direction or the radial direction.

A plasma processing apparatus which conducts surface processing on a sample to be processed by using plasma includes a vacuum vessel within which the plasma is generated, a lower electrode which is provided in the vacuum vessel and on which the sample to be processed is placed, an upper electrode provided so as to be opposed to the lower electrode, a gass supply unit connected to the upper electrode, a high frequency power supply for plasma generation connected to the upper electrode, and a solenoid coil for magnetic field generation. The upper electrode includes a shower plate through which first gas holes are formed, a conductor plate which is disposed at back of the shower plate and through which second gas holes are formed, a first insulation plate which is disposed in a center part of the conductor plate and through which third gas holes are formed, a second insulation plate which is disposed at back of the first insulation plate and through which fourth gas holes are formed, and an antenna basic member unit which is disposed at back of the conductor plate and which has a temperature control function unit and a gass distribution unit. A first minute gap is formed in a radial direction at an interface between the shower plate and the first insulation plate, a second minute gap is formed in a radial direction at an interface between the second insulation plate and the conductor plate, and a third minute gap is formed in a radial direction at an interface between the first insulation plate and the second insulation plate. And centers of the first gas holes, centers of the third gas holes and centers of the fourth gas holes are shifted from each other in a circumference direction or the radial direction.

According to the present invention, occurrence of abnormal discharge can be suppressed by adopting the above-described configuration to weaken the high frequency electric field near the center of the shower plate where abnormal discharge is apt to occur without hampering the temperature controllability of the shower plate, prolong the creepage distance between the gas holes of the shower plate and the conductor plate, and make it impossible to get an unobstructed view of the conductor plate directly from the plasma or the shower plate surface. Furthermore, it is possible to prevent abnormal discharge from expanding to the insulation plate or the conductor plate even if the abnormal discharge should occur.

Furthermore, since the creepage distance can be further prolonged by forming the insulation plate of two layers, abnormal discharge can be further suppressed.

Other objects, features and advantages of the invention will become apparent from the following description of the embodiments of the invention taken in conjunction with the accompanying drawings.

### BRIEF DESCRIPTION OF THE DRAWINGS

FIG. 1 is a basic configuration diagram in a first embodiment of the present invention;

FIG. 2 is a diagram for explaining the whole of an apparatus on which a structure near a shower plate according to the first embodiment is mounted;

FIG. 3 is a diagram for explaining an arrangement of gas holes in the first embodiment;

FIG. 4 is another diagram for explaining an arrangement of gas holes in the first embodiment;

FIG. 5 is an enlargement diagram of a gas hole part near the shower plate center in a conventional structure; and

FIG. 6 is a basic configuration diagram in a second embodiment of the present invention.

### DETAILED DESCRIPTION OF THE EMBODIMENTS

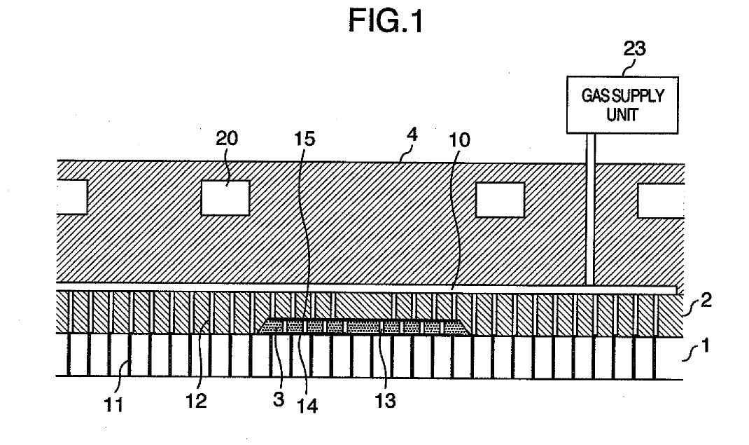

Hereafter, a first embodiment of the present invention will be described with reference to FIGS. 1 to 4.

FIG. 1 is a basic configuration diagram in the first embodiment of the present invention.

FIG. 1 shows arrangement of a shower plate 1, a conductor plate 2 disposed at the back of the shower plate 1, and an insulation plate 3 disposed at an interface between the shower plate 1 and the conductor plate 2 in a center part of the conductor plate 2.

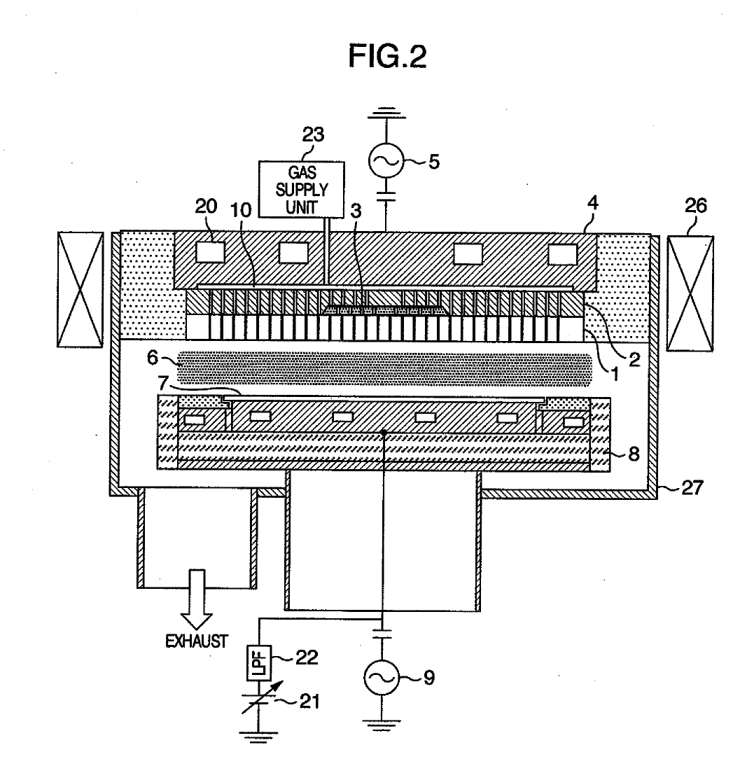

FIG. 2 is a diagram showing the whole of an apparatus including a structure in the vicinity of the shower plate 1 shown in FIG. 1.

The shower plate 1 is formed of silicon, the conductor plate 2 is formed of aluminum, and the insulation plate 3 is formed of quartz. The diameter of a surface of the shower plate 1 in contact with plasma (exposed surface) is set equal to Φ325 mm which is larger than the diameter of a sample to be processed 7, and the thickness of the shower plate 1 is set equal to 10 mm. In the present embodiment, the exposed diameter of the shower plate 1 is set equal to Φ325 mm. As a matter of course, however, similar effects can be obtained even if the exposed diameter of the shower plate 1 is set equal to a value in the range from nearly the diameter of the sample to be processed 7 (for example, Φ300 mm) to nearly Φ380 mm. Since the shower plate 1 is typically an article of consumption, however, the cost increases as the diameter becomes large. Therefore, it is desirable to restrict the diameter to a value which provides necessary performance.

The insulation plate 3 may take the shape of a disk. In the present embodiment, the insulation plate 3 takes the shape of a truncated cone. By using the shape of a truncated cone, three effects described hereafter are obtained.

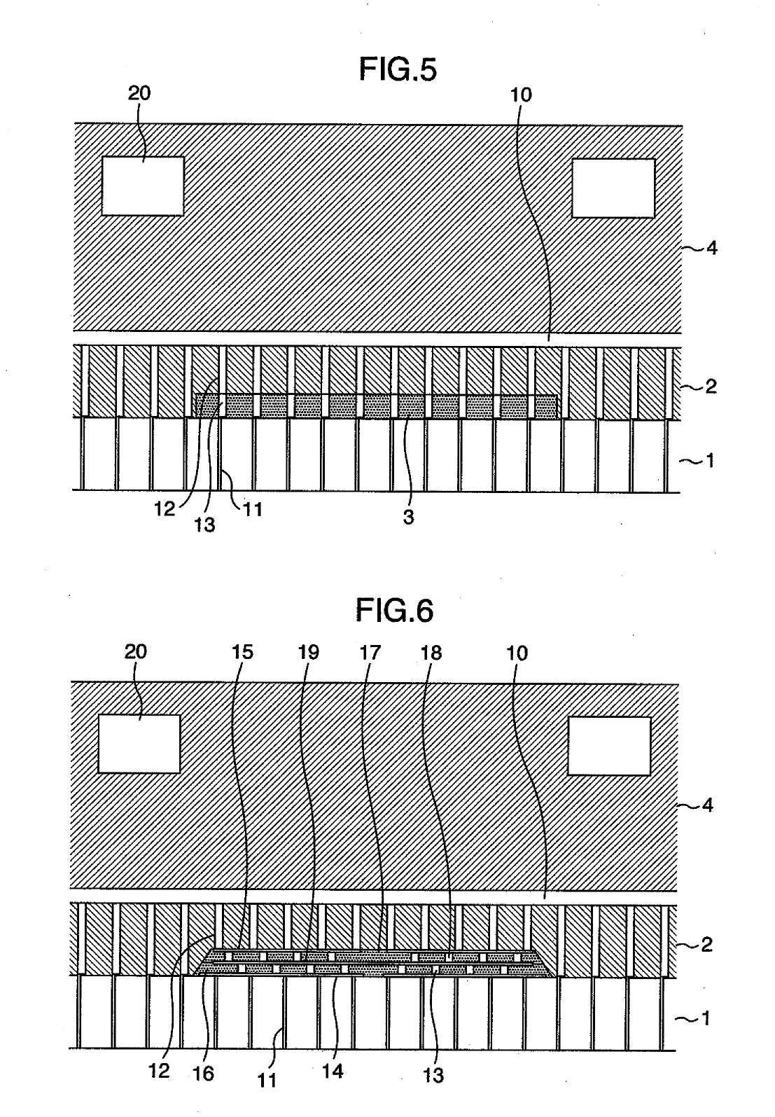

A first point will now be described. In the disk shape in the related art shown in FIG. 5, a gap is necessarily caused in an edge part of the disk, and abnormal discharge occurs in the gap in some cases. However, it becomes possible to dispose the insulation plate 3 so as to bring its slope into contact with a slope of the conductor plate 2 and suppress the gap by providing the insulation plate 3 with the shape of the truncated cone as in the present embodiment. As for a second point, the distance on the slope of the edge part can be made longer as compared with the disk shape having the same plate thickness by using the shape of the truncated cone. A resultant prolonged creepage distance is effective in suppressing the abnormal discharge. As for a third point, the electric field generated between the shower plate 1 and the conductor plate 2 has a main component in a direction perpendicular to the plane of the conductor plate 2. Accordingly, the direction of the slope between the truncated cone and the conductor plate 2 obtained by using the shape of the truncated cone differs from the direction of the electric field. As a result, an effect of suppressing abnormal discharge in the gap part is obtained. Owing to the three points heretofore described, the risk of the abnormal discharge at ends of the insulation plate 3 can be reduced remarkably as compared with the disk shape by causing the insulation plate 3 to take the shape of the truncated cone.

The diameter of the bottom surface of the insulation plate 3 is set equal to 100 mm, and the thickness of the insulation plate 3 is set equal to 5 mm.

An antenna basic member unit 4 including a temperature control function unit 20 which controls the temperature by letting flow a liquid coolant and a gass distribution unit 10 is disposed at the back (over the top) of the conductor plate 2. The antenna basic member unit 4 having the temperature control and gas scattering function is also formed of aluminum.

The whole of the shower plate 1, the conductor plate 2, the insulation plate 3 and the basic member unit 4 constitutes an upper electrode. The upper electrode is disposed so as to be opposed to a lower electrode 8 which is disposed in a vacuum vessel and which has the sample to be processed 7 placed thereon. Plasma 6 is generated over the sample to be processed 7 by interaction between a high frequency supplied from a high frequency power supply for plasma generation 5 connected to the upper electrode and a magnetic field generated by letting flow a current through a solenoid coil for magnetic field generation 26. The solenoid coil 26 is an electromagnetic coil having winding wound in a circumference direction of a vacuum vessel 27 in which plasma is generated. Therefore, the magnetic field generated by the solenoid coil has lines of magnetic force which are in a direction perpendicular to the horizontal plane of the shower plate 1. A magnetic field having lines of magnetic force which are nearly perpendicular for the center axis of the shower plate 1, but having a magnetic force line component in the horizontal direction with respect to the radial direction of the shower plate 1 is formed.

A high frequency voltage from a high frequency power supply 9 which is different from the high frequency power supply for plasma generation 5 is supplied to the lower electrode 8. The sample to be processed 7 is subjected to electrostatic chucking by a direct current voltage applied to the lower electrode 8 from a direct current power supply 21 via a low pass filter 22.

Process gas supplied by a gass supply unit 23 connected to the upper electrode is scattered by the gass distribution unit 10, and led to second gas holes 12 bored through the conductor plate 2 and third gas holes 13 bored through the insulation plate 3 which is disposed in the center part of the conductor plate 2. The gas led to the second gas holes 12 and the third gas holes 13 is led to a discharge space via first gas holes 11 bored through the shower plate 1 and converted to plasma.

As shown in FIG. 1, the third gas holes bored through the insulation plate 3 and the first gas holes bored through the shower plate 1 are arranged so as to be different in hole position.

There is a first minute gap 14 in a radial direction at an interface between the shower plate 1 and the insulation plate 3. Furthermore, there is a second minute gap 15 in a radial direction at an interface between the insulation plate 3 and the conductor plate 2. The supplied gas is scattered in these minute gaps in the horizontal direction.

The gas is supplied to the first gas holes 11 located near the center of the shower plate 1 via the gass distribution unit 10, the second gas holes 12, the second minute gap 15, the third gas holes 13 and the first minute gap 14.

Parts of the conductor plate 2 having no insulation plate 3 and the shower plate 1 are in contact with each other at the interface between them so as to stick to each other. Owing to this contact, the shower plate 1 and the conductor plate 2 are brought into electric contact, and a function of the conductor plate 2 to cool the shower plate 1 heated by the plasma 6 is obtained.

In the present embodiment, the first minute gap 14 and the second minute gap 15 are set in thickness to a value in the range of 0.05 to 0.1 mm both inclusive.

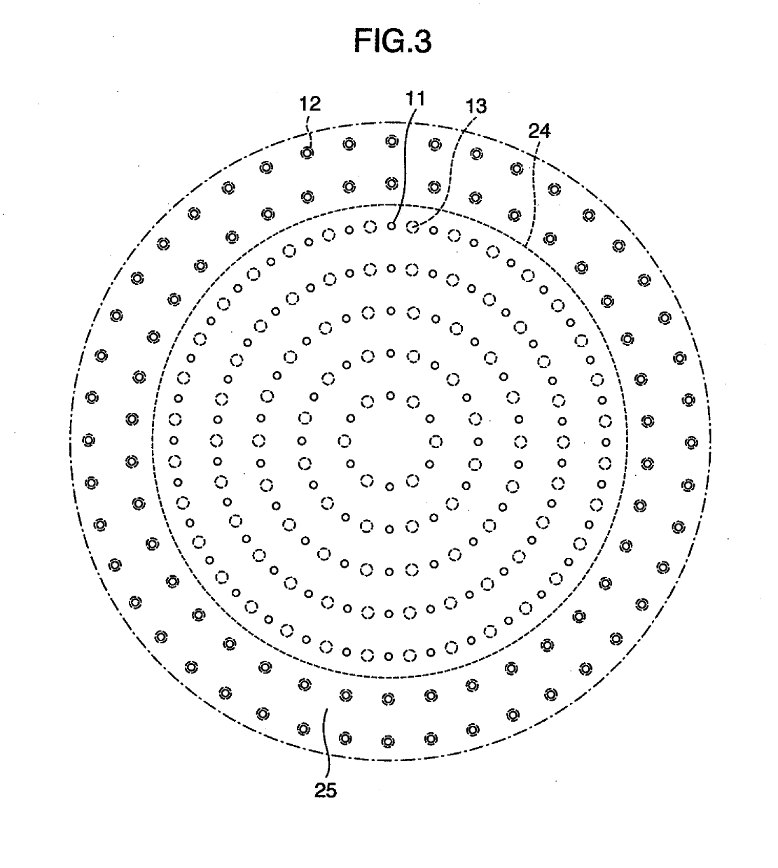

FIG. 3 is an arrangement diagram of the first gas holes 11 and the third gas holes 13 only in the center vicinity part viewed from the plasma side surface of the shower plate 1 shown in FIG. 1. A region 24 in which the insulation plate 3 is installed is represented by a dashed line. A region between the dashed line and a dot-dash line drawn outside represents a region 25 where the insulation plate 3 is not installed, and represents a part of the shower plate.

Gas holes represented by solid lines are the first gas holes 11 bored through the shower plate 1. Gas holes represented by dashed lines in the installation region 24 of the insulation plate 3 are the third gas holes 13 bored through the insulation plate 3. Gas holes represented by dashed lines in the non-installation region 25 of the insulation plate 3 are the second gas holes 12 bored through the conductor plate 2.

The diameter of the first gas holes 11 bored through the shower plate 1 is set equal to 0.5 mm, and the diameter of the second gas holes 12 bored through the conductor plate 2 and the third gas holes 13 bored through the insulation plate 3 is set equal to 0.8 mm. The diameter of the first gas holes 11 bored through the shower plate 1 and the diameter of the second gas holes 12 bored through the conductor plate 2 are made different from each other to provide position alignment of gas holes between the shower plate 1 and the conductor plate 2 in close contact with a margin, cause gas hole positions to overlap without fail, and ensure gas passage.

The first gas holes 11 of the shower plate 1 and the third gas holes 13 of the insulation plate 3 are arranged so as to have centers shifted in the circumference direction, and gas is supplied via the first minute gap 14. Therefore, it is not necessarily required to provide the diameters of holes with a difference. In the present embodiment, however, the diameter of the third gas holes 13 is set equal to the diameter of the second gas holes 12 bored through the conductor plate 2.

In the non-installation region 25 of the insulation plate 3, the shower plate 1 and the conductor plate 2 are arranged so as to directly stick to each other. Therefore, the second gas holes 12 bored through the conductor plate 2 and the first holes 11 bored through the shower plate 1 are arranged so as to be coincident with each other.

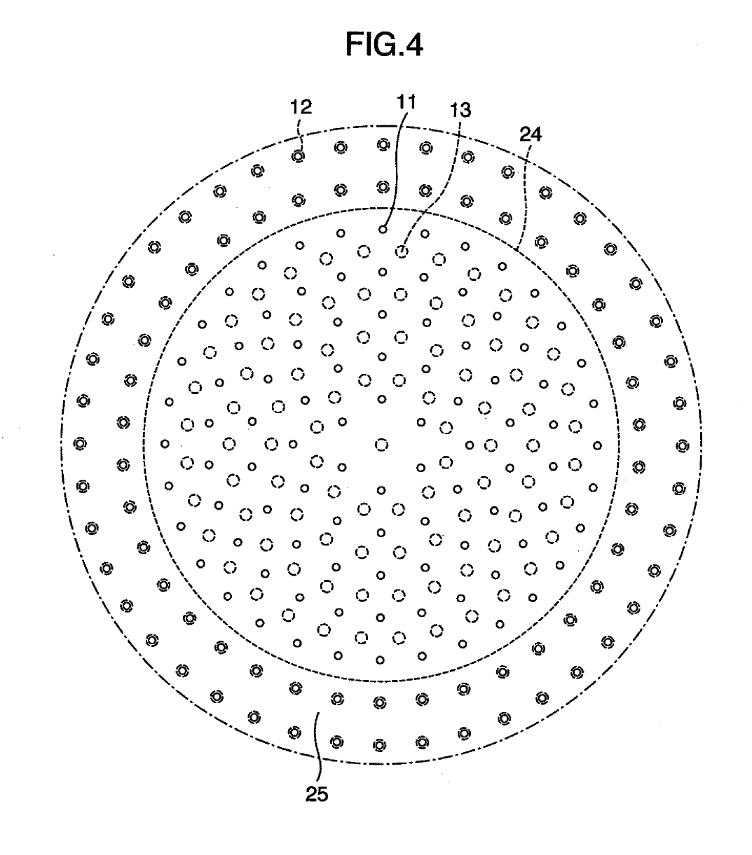

FIG. 4 shows an embodiment which differs from that shown in FIG. 3 in arrangement of gas holes.

In FIG. 3, the third gas holes 13 of the insulation plate 3 are shifted from the first gas holes 11 of the shower plate 1 in the circumference direction so as not to be coincident in hole position. In FIG. 4, however, the third gas holes 13 of the insulation plate 3 are shifted from the first gas holes 11 of the shower plate 1 in the circumference direction in the radial direction. Effects of arrangements shown in FIGS. 3 and 4 are substantially the same.

How abnormal discharge occurs in the conventional structure will now be described with reference to FIG. 5 in order to explain effects of the first embodiment.

FIG. 5 is an enlarged diagram of a gas hole part in the vicinity of the center of the shower plate in the conventional structure.

It is possible to suppress the abnormal discharge in gas holes of a shower plate 1 to some degree by moderating the electric field strength in the vicinity of the center of the shower plate 1 with an insulation plate used in JP-A-2003-68718.

In the conventional structure shown in FIG. 5, however, first gas holes 11 bored through the shower plate 1, third gas holes 13 bored through an insulation plate disposed at the back of the shower plate 1, and second gas holes 12 bored through a conductor plate 2 are arranged on straight lines. According to the discharge condition, a sufficient discharge suppression effect cannot be obtained because of this arrangement in some cases.

As for occurrence of abnormal discharge in the gas holes which is the subject of the present invention, there are mainly discharges of two kinds hereafter described.

Discharge of a first kind is discharge between plasma and the first gas holes bored through the shower plate 1. A potential difference (self bias) is caused between plasma 6 and the shower plate 1 by a high frequency voltage generated by a high frequency power supply for plasma generation 5. Typically, between the shower plate 1 and the plasma, ion sheath is formed by the potential difference, resulting in stability. In the vicinity of the gas holes and in the gas holes, however, local discharge is apt to occur because the gas pressure is high. This discharge is not restricted to within the gas holes of the shower plate 1, but expands to the third gas holes 13 bored through the insulation plate 3 and the second gas holes 12 bored through the conductor plate 2, resulting in causes of instability of the plasma 6 and occurrence of dust particles.

Abnormal discharge of a second kind is abnormal discharge which occurs in the third gas holes 13 of the insulation plate 3.

Originally, the shower plate 1 and the conductor plate 2 are in electric contact with each other. Even if the insulation plate 3 is inserted only in the center part, therefore, the shower plate 1 and the conductor plate 2 assume the same potential from the viewpoint of direct current. Since the high frequency voltage for plasma generation is high in frequency, however, a high frequency potential difference is generated in the thickness direction of the insulation plate 3 between the shower plate 1 and the conductor plate 2 under the influence of inductance on surfaces of the shower plate 1 and the conductor plate 2 in contact with the insulation plate 3 and incompleteness of the contact. Discharge is generated in the third gas holes 13 of the insulation plate 3 by the potential difference. The discharge expands up to insides of the first gas holes 11 bored through the shower plate 1 and the second gas holes 12 bored through the conductor plate 2. This becomes causes of instability of the plasma 6 and dust particles in the same way as the foregoing description.

In view of the occurrence causes of abnormal discharge heretofore described, in the first embodiment, the first gas holes 11 bored through the shower plate 1 and the third gas holes 13 bored through the insulation plate 3 are arranged so as to be shifted from each other as shown in FIGS. 1 and 3. This structure prevents abnormal discharge generated in the first gas holes 11 (by a potential difference between the plasma 6 and the shower plate 1) from advancing to the third gas holes 13 bored through the insulation plate 3 and the second gas holes 12 bored through the conductor plate 2.

In addition, since the creepage distance between the first gas holes bored through the shower plate 1 and the conductor plate 2 is prolonged, occurrence itself of the abnormal discharge becomes hard to occur.

In other words, in order for the abnormal discharge to advance from the shower plate 1 to the conductor plate 2 in the structure shown in FIG. 1, it is necessary for the discharge to advance in the first minute gap 14 in the radial direction. Since the electric field generated in the first minute gap 14 assumes the thickness direction of the gap, however, advancement of the discharge in the radial direction is hard to occur. As for the thickness direction of the first minute gap 14, a sufficient acceleration distance for electrons cannot be obtained and the discharge occurrence can be suppressed by setting the thickness of the first minute gap 14 equal to a value in the range of 0.05 to 0.1 mm both inclusive as described with reference to the first embodiment.

Furthermore, in the present embodiment shown in FIG. 2, a magnetic field which is nearly perpendicular to the radial direction of the first minute gap 14 is formed by the solenoid coil 26. Since electrons are prevented by the magnetic field from being accelerated in the radial direction, a structure in which the abnormal discharge is harder to occur is obtained.

In the present embodiment, a great part of the shower plate 1 is in contact with the conductor plate which is adjusted in temperature. Therefore, cooling of the shower plate 1 which becomes excessive in the related art described in JP-A-2007-5491 is not hampered, either.

In the present embodiment, the spacing of the first minute gap 14 is set equal to a value in the range of 0.05 to 0.1 mm both inclusive. If the gas pressure in the shower plate is in a range of approximately 2,000 Pa or less, discharge is not caused in the thickness direction even when the spacing is 0.5 mm or less. Under conditions such as the gas flow rate used in the typical dry etching apparatus, the pressure within the shower plate is 2,000 Pa or less. If the first minute gap 14 is 0.5 mm or less, therefore, similar effects can be obtained. In the first embodiment shown in FIG. 1, it becomes possible to remarkably expand the abnormal discharge suppression region (the high frequency power for plasma generation and gas flow rate released from the shower plate) as compared with the conventional structure.

A second embodiment of the present invention will now be described with reference to FIG. 6.

FIG. 6 is a basic configuration diagram in the second embodiment of the present invention.

In the second embodiment, the insulation plate in the first embodiment is constituted as a two-layer structure having a first insulation plate 16 and a second insulation plate 17. The first insulation plate 16 and the second insulation plate 17 may take the shape of a disk. However, both the first insulation plate 16 and the second insulation plate 17 take the shape of a truncated cone.

Gas holes bored through the first insulation plate 16 are referred to as third gas holes 13. Gas holes bored through the second insulation plate 17 which is disposed at the back of the first insulation plate 16 are referred to as fourth gas holes 18.

A first minute gap 14 is formed in the radial direction at an interface between the shower plate 1 and the first insulation plate 16. A second minute gap 15 is formed in the radial direction at an interface between the second insulation plate 17 and the conductor plate 2. A third minute gap 19 is formed at an interface between the first insulation plate 16 and the second insulation plate 17. Every minute gap is set equal to a value in the range of 0.05 to 0.1 mm both inclusive. Supplied gas is spread through these minute gaps in the horizontal direction.

The first gas holes 11 bored through the shower plate 1, the third gas holes 13 bored through the first insulation plate 16, and the fourth gas holes 18 bored through the second insulation plate 17 are arranged so as to have a shift, in the circumference direction or the radial direction, between center positions of contiguous gas holes.

Gas supplied to a center part of the conductor plate 2 is supplied to the shower plate 1 via the second gas holes 12, the second minute gap 15, the fourth gas holes 18, the third minute gap 19, the third gas holes 13 and the first minute gap 14.

Owing to the structure shown in FIG. 6, it is possible to make the creepage distance between the shower plate 1 and the conductor plate 2 via gas holes longer than that in the first embodiment shown in FIG. 1, and resistance to the abnormal discharge can be further enhanced.

Furthermore, it is possible to suppress abnormal discharge (the abnormal discharge of the second kind) caused between the insulation plates by a potential difference between the shower plate 1 and the conductor plate 2 by providing the insulation plate with the two-layer structure and using the structure in which centers of the gas holes are not aligned on one straight line.

It is possible to shorten the acceleration distance of electrons and reduce the occurrence ratio of electrons leading to discharge, by shortening the straight line distance in the insulation plates. At the same time, the risk of occurrence of abnormal discharge caused by a potential difference in the gas holes of the insulation plates can be reduced as an effect of increased creepage distance.

In the second embodiment, the insulation plate has a two-layer structure. As a matter of course, however, resistance to abnormal discharge can be improved by further dividing the insulation plate to at least two layers and shifting phases of gas holes bored through respective insulation plates.

In the first embodiment and the second embodiment, quartz is used for the insulation plate. As a matter of course, however, similar effects can be obtained even if another material is used, as long as the material is a material having a comparatively low dielectric loss and having a favorite insulation property such as aluminum oxide, aluminum nitride, yttrium oxide or polyimide.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus which conducts surface processing on a sample to be processed by using plasma, the plasma processing apparatus comprising:
a vacuum vessel within which the plasma is generated;
a lower electrode which is provided in the vacuum vessel and on which the sample to be processed is placed;
an upper electrode provided so as to be opposed to the lower electrode;
a gass supply unit connected to the upper electrode;
a high frequency power supply for plasma generation connected to the upper electrode; and
a solenoid coil for magnetic field generation,
wherein
the upper electrode comprises a shower plate through which first gas holes are formed, a conductor plate which is disposed at back of the shower plate and through which second gas holes are formed, an insulation plate which is disposed in a center part of the conductor plate and through which third gas holes are formed, and an antenna basic member unit which is disposed at back of the conductor plate and which has a temperature control function unit and a gass distribution unit,
a first minute gap is formed in a radial direction at an interface between the shower plate and the insulation plate, and a second minute gap is formed in a radial direction at an interface between the insulation plate and the conductor plate, and
centers of the first gas holes are shifted from centers of the third gas holes in a circumference direction or the radial direction.

2. The plasma processing apparatus according to claim 1, wherein the insulation plate takes a shape of a truncated cone.

3. A plasma processing apparatus which conducts surface processing on a sample to be processed by using plasma, the plasma processing apparatus comprising:
a vacuum vessel within which the plasma is generated;
a lower electrode which is provided in the vacuum vessel and on which the sample to be processed is placed;
an upper electrode provided so as to be opposed to the lower electrode;
a gass supply unit connected to the upper electrode;
a high frequency power supply for plasma generation connected to the upper electrode; and
a solenoid coil for magnetic field generation,
wherein
the upper electrode comprises a shower plate through which first gas holes are formed, a conductor plate which is disposed at back of the shower plate and through which second gas holes are formed, a first insulation plate which is disposed in a center part of the conductor plate and through which third gas holes are formed, a second insulation plate which is disposed at back of the first insulation plate and through which fourth gas holes are formed, and an antenna basic member unit which is disposed at back of the conductor plate and which has a temperature control function unit and a gass distribution unit,
a first minute gap is formed in a radial direction at an interface between the shower plate and the first insulation plate, a second minute gap is formed in a radial direction at an interface between the second insulation plate and the conductor plate, and a third minute gap is formed in a radial direction at an interface between the first insulation plate and the second insulation plate, and
centers of the first gas holes, centers of the third gas holes and centers of the fourth gas holes are shifted from each other in a circumference direction or the radial direction.

4. The plasma processing apparatus according to claim 3, wherein the first and second insulation plates take a shape of a truncated cone.
